(19) United States
(12) Patent Application Publication
(10) Pub. No.: US 2011/0169079 A1
(43) Pub. Date: Jul. 14, 2011

(54) Semiconductor device having an overlapping multi-well implant and method for fabricating same

(75) Inventors: Akira Ito, Irvine, CA (US); Henry Kuo-Shun Chen, Irvine, CA (US); Bruce Chih-Chieh Shen, Irvine, CA (US)

(73) Assignee: BROADCOM CORPORATION, Irvine, CA (US)

(21) Appl. No.: 12/657,162

(22) Filed: Jan. 14, 2010

(51) Int. Cl. H01L 29/78; H01L 21/30

(52) U.S. Cl. 257/337; 438/433; 257/E29.256; 257/E21.211

(57) ABSTRACT

According to one embodiment, a semiconductor device having an overlapping multi-well implant comprises an isolation structure formed in a semiconductor body, a first well implant formed in the semiconductor body surrounding the isolation structure, and a second well implant overlapping at least a portion of the first well implant. The disclosed semiconductor device, which may be an NMOS or PMOS device, can further comprise a gate formed over the semiconductor body adjacent to the isolation structure, wherein the first well implant extends a first lateral distance under the gate and the second well implant extends a second lateral distance under the gate, and wherein the first and second lateral distances may be different. In one embodiment, the disclosed semiconductor device is fabricated as part of an integrated circuit including a power management circuit or a power amplifier.

### BACKGROUND OF THE INVENTION

1. Field of the Invention

The present invention is generally in the field of semiconductors. More specifically, the present invention is in the field of fabrication of semiconductor devices.

2. Background Art

Due to its numerous advantages, such as high density, low power consumption, and relative noise immunity, for example, complementary metal-oxide-semiconductor (CMOS) technology is widely used in integrated circuits (ICs) to provide control logic for modern electronic systems. Standard CMOS transistors, however, are typically low voltage devices. Consequently power operations, such as power switching and voltage regulation, are usually performed by high power versions of metal-oxide-semiconductor field-effect transistors (MOSFETs), such as lateral diffused metal-oxide-semiconductor (LDMOS) devices, often fabricated alongside the CMOS logic devices on the IC die.

As the performance requirements placed on modern electronic systems grow ever more stringent, power losses within the power semiconductor devices, as well as factors affecting switching speed and output response, become increasingly important. One important measure of LDMOS device performance is its breakdown voltage, which should preferably be high, while another is its ON-resistance, or R_{dson}, which should preferably be quite low.

Conventional attempts to lower R_{dson} in an LDMOS device may include manipulating the dimensions of various device layout parameters. For example, the R_{dson} of an LDMOS device can be reduced by reducing the width of the shallow trench isolation (STI) structure formed between the gate and the highly doped drain region, or by increasing the overlap of the gate over the drain extension well surrounding the STI structure. However, those conventional modifications of the LDMOS device undertaken to advantageously reduce R_{dson}, may concurrently and undesirably result in a reduced breakdown voltage for the LDMOS device, an increased junction capacitance of the device, or both.

Thus, there is a need to overcome the drawbacks and deficiencies in the art by delivering a solution compatible with existing CMOS fabrication process flows, which provides a power MOSFET configured to concurrently exhibit low R_{dson} and robust resistance to voltage breakdown.

### SUMMARY OF THE INVENTION

A semiconductor device having an overlapping multi-well implant and method for fabricating same, substantially as shown in and/or described in connection with at least one of the figures, as set forth more completely in the claims.

### BRIEF DESCRIPTION OF THE DRAWINGS

FIG. 1 is a block diagram showing a conventional lateral diffused metal-oxide-semiconductor (LDMOS) device.

FIG. 2 is a block diagram showing an LDMOS device having an overlapping multi-well drain extension implant, according to one embodiment of the present invention.

FIG. 3 is a flowchart presenting a method for fabricating a semiconductor device having an overlapping multi-well implant, according to one embodiment of the present invention.

### DETAILED DESCRIPTION OF THE INVENTION

The present invention is directed to a semiconductor device having an overlapping multi-well implant and a method for its fabrication. Although the invention is described with respect to specific embodiments, the principles of the invention, as defined by the claims appended herein, can obviously be applied beyond the specifically described embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely example embodiments of the invention. To maintain brevity, other embodiments of the invention, which use the principles of the present invention, are not specifically described in the present application and are not specifically illustrated by the present drawings. It should be borne in mind that, unless noted is otherwise, like or corresponding elements among the figures may be indicated by like or corresponding reference numerals. Moreover, the drawings and illustrations in the present application are generally not to scale, and are not intended to correspond to actual relative dimensions.

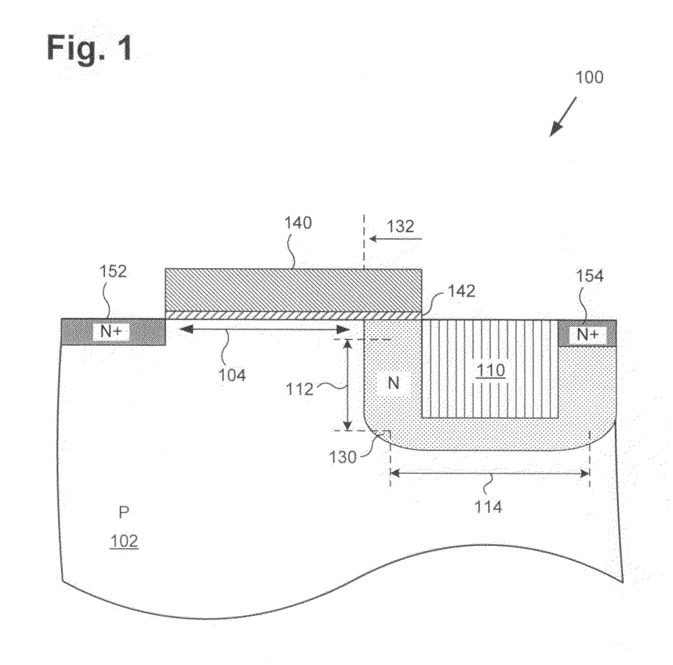

FIG. 1 is a block diagram showing a conventional lateral diffused metal-oxide-semiconductor (LDMOS) device. As shown in FIG. 1, conventional LDMOS 100, which is represented as an NMOS device, may be fabricated in P type semiconductor body 102. Conventional LDMOS 100 includes gate 140 formed on gate oxide 142, source 152, drain 154, shallow trench isolation (STI) structure 110 situated between gate 140 and drain 154, and drain extension well 130. Also shown in FIG. 1 are channel region 104, vertical region 112 of drain extension well 110, lateral region 114 of drain extension well 110, and dimension 132 corresponding to the overlap of drain extension well 130 by gate 140.

As known in the art, the combination of STI structure 110 and drain extension well 130 enable conventional LDMOS 100 to have a higher breakdown voltage than standard symmetrically arranged MOSFETs. Most of the breakdown voltage sustainable by conventional LDMOS 100 is borne by vertical region 112 of drain extension well 130. Lateral region 114 of drain extension well 130, although not contributing substantially to the ability of conventional LDMOS 100 to withstand voltage breakdown, does add to the total resistance of drain extension well 130 by contributing its series resistance between channel region 104 and drain 154, thereby undesirably increasing the ON-resistance (R_{dson}) of conventional LDMOS 100.

One known approach seeking to improve the R_{dson} of conventional LDMOS 100 includes reducing the lateral width of STI structure 110. In so doing, lateral region 114 is correspondingly reduced in length, thereby reducing its series contribution to the overall resistance of drain extension well 130. However, as device dimensions become progressively smaller, additional reductions in the lateral width of STI structure 110 may compromise the ability of conventional LDMOS device 100 to sustain the breakdown voltage necessary for it to perform reliably as a power device.

Another conventional approach to reducing R_{dson} of conventional LDMOS 100 may include increasing dimension 132 by widening the portion of drain extension well 130 under gate 140. Unfortunately, in addition to undesirably tending to reduce breakdown voltage, that approach is associated with an increase in junction capacitance between gate 140 and drain extension well 130, which can also undesirably impact the performance of conventional LDMOS 100. Consequently, the various known techniques employed in conventional approaches to reducing R_{dson} are likely to reduce the breakdown voltage of conventional LDMOS 100, and may increase its junction capacitance as well.

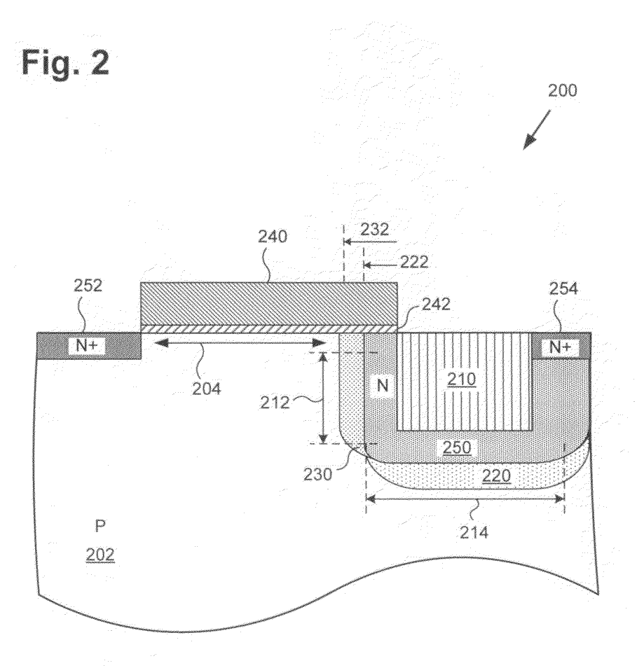

Turning to FIG. 2, FIG. 2 is a block diagram showing an LDMOS device having an overlapping multi-well drain extension implant, according to one embodiment of the present invention, that succeeds in overcoming the drawbacks and deficiencies of the conventional implementation shown in FIG. 1. LDMOS 200, in FIG. 2, which may be implemented as an NMOS or PMOS device, is suitable for use in a power management circuit or power amplifier (PA), for example. Moreover, because fabrication of LDMOS 200 can be performed using processing steps presently included in many complementary metal-oxide-semiconductor (CMOS) foundry process flows, LDMOS 200 may be fabricated alongside conventional CMOS devices, and may be monolithically integrated with CMOS logic, for example, in an integrated circuit (IC) fabricated on a semiconductor wafer or die.

It is noted that the specific features represented in FIG. 2 are provided as part of an example implementation of the present inventive principles, and are shown with such specificity as an aid to conceptual clarity. Because of the emphasis on conceptual clarity, it should be understood that the structures and features depicted in FIG. 2 may not be drawn to scale. Furthermore, it is noted that particular details such as the type of semiconductor device represented by LDMOS 200, its overall layout, and the particular dimensions attributed to its features are merely being provided as examples, and should not be interpreted as limitations.

For example, although the embodiment shown in FIG. 2 characterizes LDMOS 200 as an n-channel device, more generally, a semiconductor device according to the present inventive principles can comprise an n-channel or p-channel MOSFET. Furthermore, in some embodiments, the principles disclosed herein can be implemented to fabricate one or more fundamentally distinct device types, such as a BiCMOS device, for example.

As shown in FIG. 2, according to one embodiment of the present invention, a semiconductor device having an overlapping multi-well implant may correspond to LDMOS 200. As further shown in FIG. 2, LDMOS 200, which is represented as an NMOS device, can be fabricated in P type semiconductor body 202. LDMOS 200 comprises gate 240 formed on gate oxide 242, source 252, drain 254, and STI structure 210 adjacent gate 240. LDMOS 200 further comprises overlapping multi-well drain extension implant 250 (also referred to generally as “multi-well implant” in the present application) providing a drain extension well for the device.

Overlapping multi-well drain extension implant 250 includes first drain extension well implant 220 formed in semiconductor body 202 surrounding STI structure 204. Overlapping multi-well drain extension implant 250 also includes second drain extension well implant 230 overlapping at least a portion of first drain extension well implant 220. Also shown in FIG. 2 are channel region 204, vertical region 212 of overlapping multi-well drain extension implant 250, lateral region 214 of overlapping multi-well drain extension implant 250, and dimensions 222 and 232 corresponding respectively to the lateral distances by which first and second drain extension well implants 220 and 230 extend under gate 240.

As can be seen from FIG. 2, according to the embodiment of LDMOS 200, dimensions 222 and 232 can be different, indicating that each of first and second drain extension well implants 220 and 230 can extend for different lateral distances under gate 240. In one embodiment, for example, dimension 222 may approach zero, so that there may be very little or substantially no overlap between first drain extension well implant 220 and second drain extension well implant 230 under gate 240. In other embodiments, dimension 222 may range between nearly zero to substantially the value of dimension 232, corresponding to progressively greater overlap of first drain extension well implant 220 and second drain extension well implant 230 under gate 240.

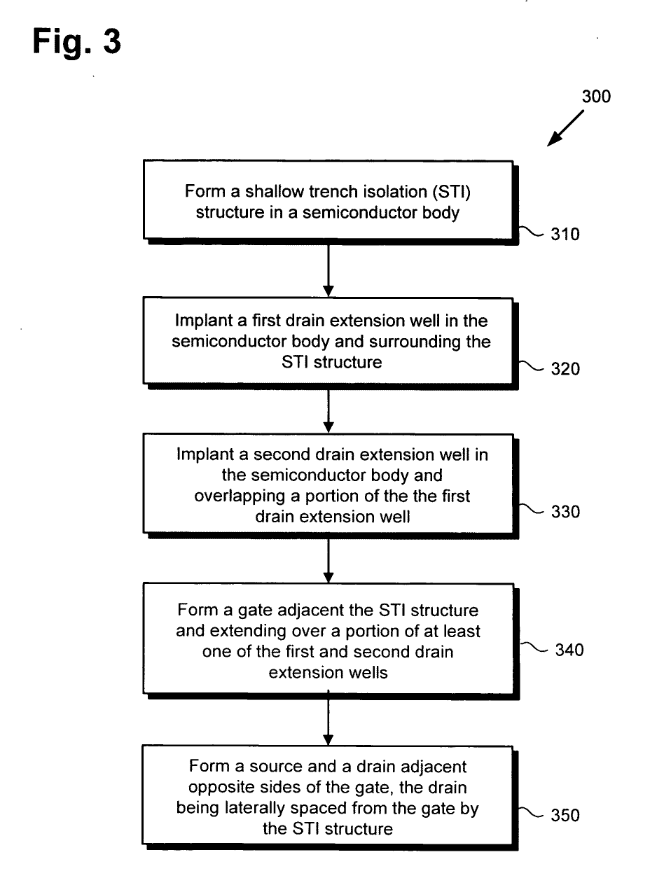

Some of the features of a semiconductor device having an overlapping multi-well implant will be further described in combination with flowchart 300, in FIG. 3, which presents an example embodiment of a method for fabricating such a device. Certain details and features have been left out of flowchart 300 that are apparent to a person of ordinary skill in the art. For example, a step may comprise one or more substeps or may involve specialized equipment or materials, as known in the art. While steps 310 through 350 indicated in flowchart 300 are sufficient to describe one embodiment of the present invention, other embodiments of the present invention may utilize steps different from those shown in flowchart 300, or may comprise more, or fewer, steps.

Referring to step 310 in FIG. 3, with additional reference to example LDMOS 200, shown in FIG. 2, step 310 of flowchart 300 comprises forming STI structure 210 in semiconductor body 202. Semiconductor body 202 may be a P type or N type semiconductor substrate, such as a silicon substrate for example, and may also comprise an epitaxial layer formed on the semiconductor substrate (epitaxial layer not explicitly shown in FIG. 2). STI structure 210 may comprise silicon dioxide, for example, and may be formed in semiconductor body 202 according to conventional semiconductor fabrication steps well known in the art.

Moving on to step 320 in FIG. 3 and continuing to refer to LDMOS 200, in FIG. 2, step 320 of flowchart 300 comprises implanting first drain extension well 220 in semiconductor body 202 surrounding STI structure 210. In one embodiment, step 320 may correspond to implanting first drain extension well 220 by performing a retrograde implant of dopants into semiconductor body 202 surrounding STI structure 210. As previously mentioned, in some embodiments, the fabrication method of flowchart 300 may be implemented using existing CMOS fabrication process flows. For example, in one embodiment, LDMOS 200 may be fabricated on a wafer concurrently undergoing CMOS logic fabrication. Thus, in such embodiments, step 320 may correspond to implanting first drain extension well 220 by performing one of a Core Well implant or an IO Well implant procedure, as known in the art.

Continuing with step 330 of flowchart 300, step 330 comprises implanting second drain extension well 230 in semiconductor body 202 and overlapping a portion of first drain extension well 220. Step 330 results in formation of overlapping multi-well drain extension implant 250. In some embodiments, a boundary of second drain extension well implant 230 may be laterally offset from a corresponding boundary of first drain extension well implant 220. For example, as shown in FIG. 2, such a lateral offset is represented by the difference between dimension 232 and dimension 222, indicating an offset of the respective drain extension well boundaries under gate 240.

As is true for implantation of first drain extension well 220, in step 320, step 330 may correspond to implanting second drain extension well 230 by performing a retrograde implant of dopants into semiconductor body 202. Moreover, as is also true for step 320 described above, step 330 may correspond to implanting second drain extension well 230 by performing one of a CMOS Core Well implant or a CMOS IO Well implant procedure.

Moving now to step 340 of flowchart 300, step 340 comprises forming gate 240 adjacent STI structure 210 and extending over a portion of at least one of first or second drain extension wells 220 and 230. Gate 240 may comprise polysilicon, for example, and may be formed over a suitable gate oxide 242, such as silicon dioxide, by the appropriate known CMOS fabrication step(s).

As shown in FIG. 2, in some embodiments, gate 240 may overlap portions of both first drain extension well 220 and second drain extension well 230, where first and second drain extension wells 220 and 230 extend for different lateral distances under gate 240. For example, in one embodiment, dimension 232 may be approximately 0.15 μm to 0.25 μm (micrometers), while the difference between dimensions 232 and 222, e.g., the lateral offset of first drain extension well 220 and second drain extension well 230 under gate 240, may be approximately 0.05 μm. However, as previously noted, dimension 222 may range from nearly or substantially zero percent, to substantially one hundred percent of dimension 232.

It is noted that although the present discussion has characterized well implant 220 as the “first” well implant and well implant 230 as the “second” well implant, those representations should not be interpreted as limiting or restrictive. The foregoing characterizations of the well implants comprised by overlapping multi-well drain extension implant 250 have been provided merely to facilitate reference to the embodiment of the present invention shown in FIG. 2. In other embodiments, for example, well implant 230 may correspond to a “first” well implant of an overlapping multi-well implant and extend farther under gate 240, e.g., according to dimension 232, than a “second” well implant corresponding to well implant 220. It is further noted that although the present discussion characterizes an overlapping multi-well implant as comprising first and second well implants, more generally, an overlapping multi-well implant according to the present inventive principles may comprise a plurality of individual well implants overlapping one another to various extents.

Continuing with step 350 of FIG. 3, step 350 of flowchart 300 comprises forming source 252 and drain 254 adjacent opposite sides of gate 240. As shown in FIG. 2, drain 254 is laterally spaced from gate 240 by STI structure 210. As is the case for preceding step 340, formation of source 252 and drain 254 may be performed according to known CMOS fabrication processes.

Example LDMOS 200, fabricated according to the method embodied by flowchart 300, provides several advantages over conventional LDMOS devices. For example, by utilizing an overlapping multi-well implant to form the drain extension region of LDMOS 200, the series resistance presented by lateral region 214 may be significantly reduced, to thereby reducing the R_{dson} of LDMOS 200. In addition, the multi-well implant approach disclosed by flowchart 300 results in a reduction in the drain resistance near the interface of multi-well drain extension implant 250 and gate oxide 242. Moreover, by laterally offsetting the first and second drain extension well implants under gate 240, the present approach enables substantial avoidance of the reductions in breakdown voltage along vertical region 212 associated with conventional approaches to reducing R_{dson}, resulting in only nominal changes in the breakdown performance of the device. Furthermore, the numerous advantages associated with the present approach can be realized using existing CMOS process flows, making integration of power devices such as LDMOS 200 and CMOS logic devices on a common IC efficient and cost effective.

From the above description of the invention it is manifest that various techniques can be used for implementing the concepts of the present invention without departing from its scope. Moreover, while the invention has been described with specific reference to certain embodiments, a person of ordinary skill in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many rearrangements, modifications, and substitutions without departing from the scope of the invention.

1. A semiconductor device having an overlapping multi-well implant, said semiconductor device comprising:
an isolation structure formed in a semiconductor body;
a first well implant formed in said semiconductor body and surrounding said isolation structure; and
a second well implant overlapping at least a portion of said first well implant.

2. The semiconductor device of claim 1, further comprising:
a gate formed over said semiconductor body adjacent said isolation structure;
said first well implant extending a first lateral distance under said gate and said second well implant extending a second lateral distance under said gate.

3. The semiconductor device of claim 1, wherein said semiconductor device comprises a p-channel metal-oxide-semiconductor (PMOS) device.

4. The semiconductor device of claim 1, wherein said semiconductor device comprises an n-channel metal-oxide-semiconductor (NMOS) device.

5. The semiconductor device of claim 1, wherein said semiconductor device is selected from the group consisting of an LDMOS device and a BiCMOS device.

6. The semiconductor device of claim 1, wherein at least one of said first well implant and said second well implant comprises a retrograde well implant.

7. The semiconductor device of claim 1, wherein one of said first well implant and said second well implant is characterized by being an IO Well implant performed during a CMOS logic fabrication process.

8. The semiconductor device of claim 1, wherein one of said first well implant and said second well implant is characterized by being a Core Well implant performed during a CMOS logic fabrication process.

9. An integrated circuit (IC) fabricated on a semiconductor die, said IC including a semiconductor device having an overlapping multi-well implant, said semiconductor device comprising:
an isolation structure formed in a semiconductor body;
a first well implant formed in said semiconductor body and surrounding said isolation structure; and
a second well implant overlapping at least a portion of said first well implant.

10. The IC of claim 9, wherein said IC comprises at least one power management circuit, and at least one logic circuit.

11. The IC of claim 9, wherein said IC comprises a power amplifier.

12. A method for fabricating a semiconductor device having an overlapping multi-well implant, said method comprising:
forming an isolation structure in a semiconductor body;
implanting a first well in said semiconductor body surrounding said isolation structure;
implanting a second well in said semiconductor body, said second well overlapping at least a portion of said first well.

13. The method of claim 12, further comprising forming a gate over said semiconductor body adjacent said isolation structure, wherein said first well implant extends a first lateral distance under said gate and said second well implant extends a second lateral distance under said gate.

14. The method of claim 12, wherein fabricating said semiconductor device comprises a fabricating a p-channel metal-oxide-semiconductor (PMOS) device.

15. The method of claim 12, wherein fabricating said semiconductor device comprises fabricating an n-channel metal-oxide-semiconductor (NMOS) device.

16. The method of claim 12, wherein fabricating said semiconductor device comprises fabricating one of an LDMOS device and a BiCMOS device.

17. The method of claim 12, wherein implanting at least one of said first well and said second well comprises performing a retrograde well implant.

18. The method of claim 12, wherein implanting one of said first well and said second well comprises utilizing an IO Well implant during a CMOS logic fabrication process.

19. The method of claim 12, wherein implanting one of said first well and said second well comprises utilizing a Core Well implant performed during a CMOS logic fabrication process.

20. The method of claim 12, wherein fabricating said semiconductor device is performed substantially concurrently with fabrication of at least one CMOS logic device.
